(19) United States
(12) Patent Application Publication
(10) Pub. No.: US 2012/0168233 A1
(43) Pub. Date: Jul. 5, 2012

(54) ROBOTIC DEVICES AND METHODS

(75) Inventor: Jason Vaughn Clark, West Lafayette, IN (US)

(73) Assignee: PURDUE RESEARCH FOUNDATION, Indianapolis, IN (US)

(21) Appl. No.: 13/341,598

(22) Filed: Dec. 30, 2011

Related U.S. Application Data
(60) Provisional application No. 61/428,438, filed on Dec. 30, 2010.

(51) Int. Cl. B62D 57/02; H01L 41/22; B23P 11/00; H01L 41/04

(52) U.S. Cl. 180/8.1; 310/331; 74/490.01; 29/25.35; 901/1; 901/23

(57) ABSTRACT

A robot and method of manufacturing the same are disclosed. Embodiments of the robot include robots with piezoelectric appendages and microrobots of very small sizes, for example, robots with appendage lengths equal to approximately 300 μm. Further embodiments include a plurality of piezoelectric appendages, each appendage including a plurality of piezoelectric members coupled to one another at two locations, while other embodiments include appendages with piezoelectric members coupled to one another at three locations. Various embodiments are capable of jumping, walking upside down, carrying heavy loads, and/or walking with foreign object contamination in one or more appendages. Still further embodiments include energy storage members that store the energy generated by an appendage when the appendage is subject to external forces.

This application claims the benefit of U.S. Provisional Application No. 61/428,438, filed Dec. 30, 2010, the entirety of which is hereby incorporated herein by reference.

### FIELD

Various embodiments of the present invention pertain to robotic devices that move in response to commands. Various other embodiments pertain to methods of locomotion, while still other embodiments pertain to methods and apparatus for actuation.

### BACKGROUND

For over 15 years, a goal for many roboticists has been to develop a microrobot with insect-like mobility. A few recent developments in microrobotics include the use of two degree-of-freedom control of a microrobotic leg in a five-mask silicon-on-insulator (SOI) process (see FIG. 1). The DARPA-supported effort was successful in integrating several complex mechanisms including large comb drive arrays, microscale hinges, sliders, clutch, and transmission. There is also an untethered scratch drive actuator that was able move forward and make left turns on a globally-controlled interdigitated electrode platform (see FIG. 2, A is the scratch drive and B is the turning arm).

Yet another design pertains to a jumping microrobot. An inchworm motor stores potential energy in an elastic band, which when released, propels the microrobot several centimeters (see FIG. 3). These efforts successfully argued the promise of using jumping as an efficient means of mobility at the microscale. Yet another design pertains to an autonomous two legged microrobot in (see FIG. 4). The DARPA supported effort was successful in incorporating onboard control and power supply. Yet another design pertains to a three degree of freedom (3 DOF) thermally-actuated walking microrobot (see FIG. 5). The DARPA-supported effort was successful in demonstrating the control of 512 thermal bimorph actuator legs using a wave-like gate to propel it up to a speed of 250 μm/sec. It has a load carrying capability of 4 grams, about 10 times its mass. Yet another design pertains to an untethered microrobot that is capable of moving on arbitrary surfaces by the stickslip motion of passive magnetic material controlled by an external field (see FIG. 6).

### SUMMARY

Various embodiments of the present invention involved developing the mechanisms helpful for insect-like dexterity for autonomous and robust microscale robotics. Various embodiments of the present inventions include apparatus that can do one or more of the following:

1. Crawl and jump in various directions.

2. Crawl and jump in an upside down orientation if flipped on its back.

3. Traverse through harsh terrains such as sand.

4. Pick up, carry, and place loads.

5. Withstand large impacts or accelerations.

6. Recharge using vibrational energy-scavenging.

Yet other embodiments of the present invention pertain to methods of actuation, including methods incorporating multiple piezoelectric devices. In one embodiment, a plurality of slender substantially similar piezoelectric devices are mechanically coupled together at one or both ends. Actuation voltages are applied to the devices independently, resulting in a bending and/or twisting motion of the piezoelectric assembly.

This summary is provided to introduce a selection of the concepts that are described in further detail in the detailed description and drawings contained herein. This summary is not intended to identify any primary or essential features of the claimed subject matter. Some or all of the described features may be present in the corresponding independent or dependent claims, but should not be construed to be a limitation unless expressly recited in a particular claim. Each embodiment described herein is not necessarily intended to address every object described herein, and each embodiment does not necessarily include each feature described. Other forms, embodiments, objects, advantages, benefits, features, and aspects of the present invention will become apparent to one of skill in the art from the detailed description and drawings contained herein. Moreover, the various apparatuses and methods described in this summary section, as well as elsewhere in this application, can be expressed as a large number of different combinations and subcombinations. All such useful, novel, and inventive combinations and subcombinations are contemplated herein, it being recognized that the explicit expression of each of these combinations is unnecessary.

### BRIEF DESCRIPTION OF THE DRAWINGS

Some of the figures shown herein may include dimensions or may have been created from scaled drawings. However, such dimensions, or the relative scaling within a figure, are by way of example, and not to be construed as limiting.

FIG. 1: 2 DOF microrobot leg. SOI (Silicon On Insulator) Process.

FIG. 2: Scratch drive.

FIG. 3: Jumping robot.

FIG. 4: Solar powered walking robot.

FIG. 5: Thermal actuation.

FIG. 6: B-field robot.

FIG. 7: Piezoelectric beam+/−voltage causes beam to expand/contract.

FIG. 8: Schematic representation of a two-flexure leg according to one embodiment of the present invention. Graphical representation of how the upper beam contracts while lower beam expands due to voltages applied in 5V increments from 0V to 40V.

FIG. 9A: Schematic representation of an appendage (leg) showing the triple-beam configuration and out-of-plane deflection according to another embodiment of the present invention.

FIG. 9B: Nonlinear deflection of the appendage depicted in FIG. 9A.

FIG. 10A: Schematic representation of the leg of FIG. 8 showing deflections superimposed.

FIG. 10B: Schematic representation of the leg of FIG. 10A showing typical excitation voltages.

FIG. 11: Perspective schematic representation of an apparatus according to one embodiment of the present invention showing a microid in an unactuated state.

FIG. 12: Perspective schematic representation of the apparatus of FIG. 11 showing a microid in an actuated state. 40V applied to the legs; 20V applied to the mandibles. The unactuated state is superimposed.

FIG. 13: Perspective schematic representation of the apparatus of FIG. 11 showing a stages of a 200 μm step. 3 legs form a tripod.

FIG. 14: Perspective schematic representation of the apparatus of FIG. 11 showing a microid turning its heading, in a tripod stance. Its initial state is superimposed underneath it.

FIG. 15: Perspective schematic representation of the apparatus of FIG. 11 showing a directional jump q-analysis. Upward displacement vs. time for the front and back of the microid. 40V step is applied. The launch velocity is approximately 0.75 m/s, and the expected jump height is approximately 2.7 cm (approximately 270 times the height of the microid while standing).

FIG. 16: Perspective schematic representation of the apparatus of FIG. 11 showing that if flipped on its back, the microid is mobile by reversing the polarity of the voltage.

FIG. 17: Perspective schematic representation of the apparatus of FIG. 11 showing an force of 600 Gs acting vertically in both situations.

FIG. 18: Perspective schematic representation of the apparatus of FIG. 11 carrying a load on its back. The tower, which may comprise silicon, weighs approximately 3500 times the weight of the microid. Using one step at a time, the microid is able to walk and clear the ground.

FIG. 19: Perspective schematic representation of the apparatus of FIGS. 9A and 9B showing limb deflection due to particulate contamination. (Left) a hypothetical particulate lodged within an appendage, which spreads the beams apart. (Right) the opposite effect where the beams are squeezed together. In both cases, the appendage is still operational.

FIGS. 20A, 20B, and 20C show processing steps for a cross section of one appendage (leg) according to another embodiment of the present invention. FIG. 20C shows an intermediate processing step, and schematically represents three sputtered piezoelectric actuators for a single leg. The microid is then released by, for example, using an etchant such as BHF (buffered hydrofluoric acid) to remove sacrificial material such as SiO2.

FIG. 21 is a perspective schematic representation of the apparatus of FIG. 11 depicting an energy harvesting according to one embodiment of the present invention.

FIG. 22 is a schematic representation of a first processing step of a leg according to one embodiment of the present invention.

FIG. 23 is a schematic representation of a subsequent processing step following FIG. 22.

FIG. 24 is a schematic representation of a subsequent processing step following FIG. 23.

FIG. 25 is a schematic representation of a subsequent processing step following FIG. 24.

FIG. 26 is a schematic representation of a subsequent processing step following FIG. 25.

FIG. 27 is a schematic representation of a subsequent processing step following FIG. 28.

FIG. 28 is a schematic representation of a subsequent processing step following FIG. 26.

### DESCRIPTION OF THE ILLUSTRATED EMBODIMENTS

For the purposes of promoting an understanding of the principles of the invention, reference will now be made to selected embodiments illustrated in the drawings and specific language will be used to describe the same. It will nevertheless be understood that no limitation of the scope of the invention is thereby intended; any alterations and further modifications of the described or illustrated embodiments, and any further applications of the principles of the invention as illustrated herein are contemplated as would normally occur to one skilled in the art to which the invention relates. At least one embodiment of the invention is shown in great detail, although it will be apparent to those skilled in the relevant art that some features or some combinations of features may not be shown for the sake of clarity.

Any reference to “invention” within this document is a reference to an embodiment of a family of inventions, with no single embodiment including features that are necessarily included in all embodiments, unless otherwise stated. Furthermore, although there may be references to “advantages” provided by some embodiments of the present invention, other embodiments may not include those same advantages, or may include different advantages. Any advantages described herein are not to be construed as limiting to any of the claims.

Specific quantities (spatial dimensions, temperatures, pressures, times, force, resistance, current, voltage, concentrations, wavelengths, frequencies, heat transfer coefficients, dimensionless parameters, etc.) may be used explicitly or implicitly herein, such specific quantities are presented as examples only and are approximate values unless otherwise indicated. Discussions pertaining to specific compositions of matter, if present, are presented as examples only and do not limit the applicability of other compositions of matter, especially other compositions of matter with similar properties, unless otherwise indicated.

The use of an N-series prefix for an element number (NXX.XX or NXX-XX) refers to an element that is the same as the non-prefixed element (XX.XX or XX-XX), except as shown and described thereafter. As an example, an element 1020.1 (or 1020-1) would be the same as element 20.1 (or 20-1), except for those different features of element 1020.1 (or 1020-1) shown and described. Further, common elements and common features of related elements are drawn in the same manner in different figures, and/or use the same symbology in different figures. As such, it is not necessary to describe the features of 1020.1 and 20.1 (or 1020-1 and 20-1) that are the same, since these common features are apparent to a person of ordinary skill in the related field of technology.

Achieving insect-like mobility using microelectromechanical systems (MEMS) has been quite elusive. Various embodiments of the present inventions pertain to a branch of microrobotics that can be referred to as “microids”. Generally, a microid is an autonomous microrobot with insect-like dexterity in mobility (crawl, jump) and task ability (lift, push, pull loads). As used herein, the term microid refers to any small robot.

Microrobots according to some embodiments of the present invention have maximum dimensions of approximately 1 cm (centimeter). Microrobots according to other embodiments have maximum dimensions of approximately 1 mm (millimeter).

A novel piezoelectric mechanism can achieve insect-like dexterity in a microrobot. Performance of the microrobot was explored using finite element analysis that included the physics of piezoelectric material, large nonlinear deflections, and gravitation. Ground surface support and traction was emulated using a combination of pin joints and sliders. The weights of a CPU and an energy storage unit were included. We applied actuation voltages directly to the microrobot appendages for various performance analyses. Such analyses included walking or running, supporting large loads, functioning with particulate contamination, turning at a point, jumping, walking up-side-down, and withstanding large externally applied forces.

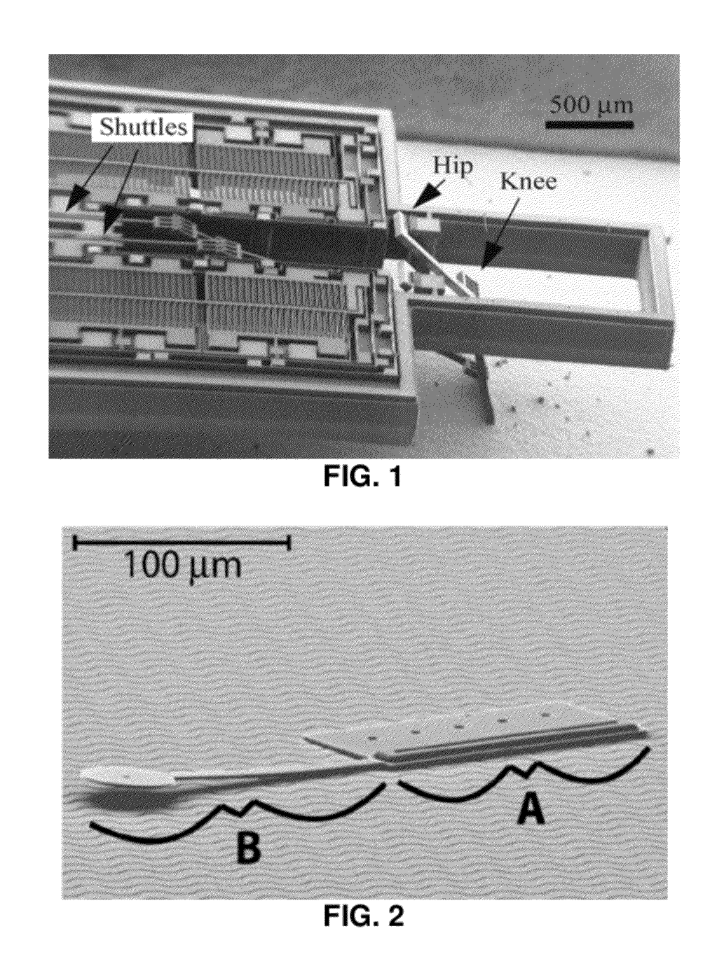

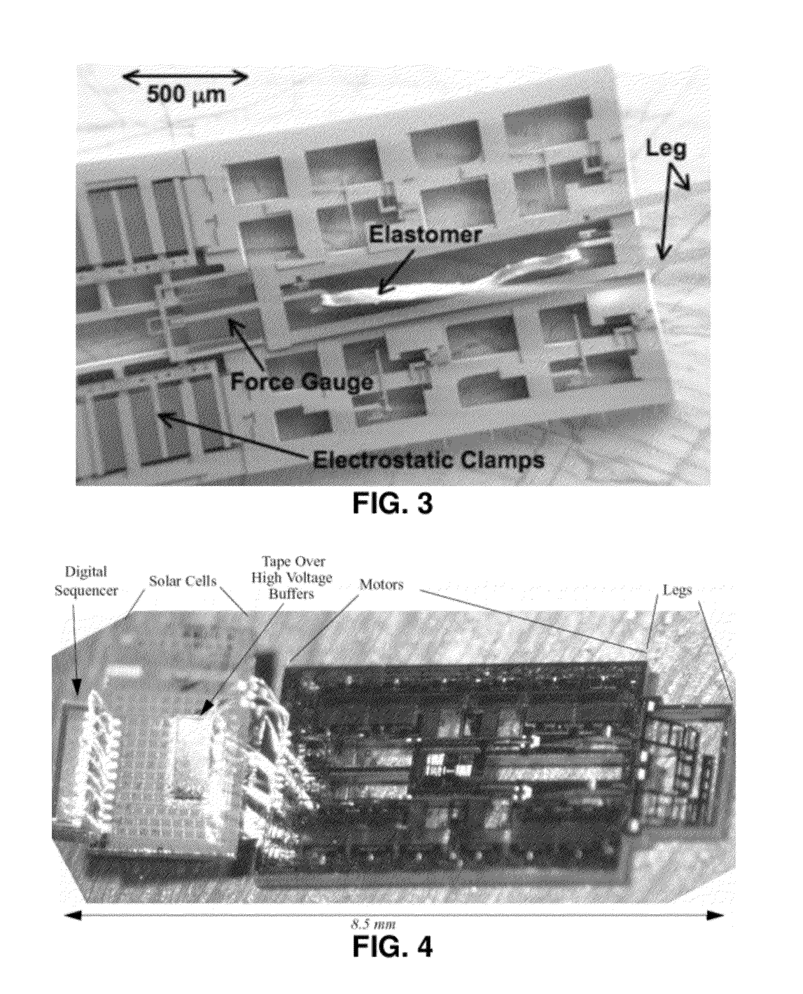

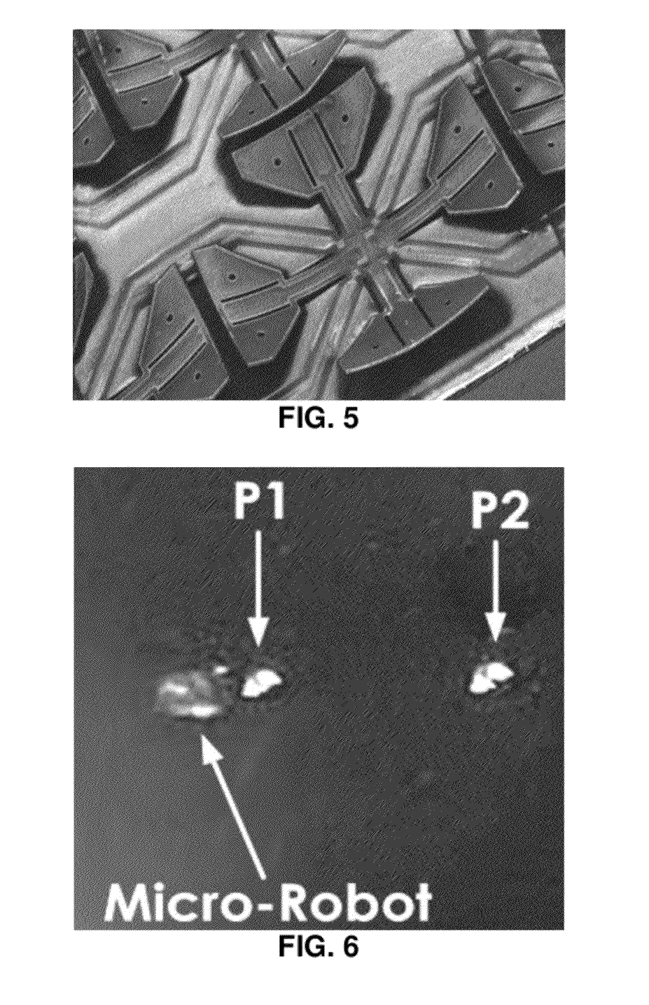

Locomotion. Although some of the microrobots shown in FIGS. 1-6 have the ability to move in at least one direction, currently they do not possess the mechanisms to maneuver in terrain that is commonly encountered by insects. For dynamic stability in uneven terrain, insects frequently use a tripod gate for locomotion. This tripod gate applies to 6-legged insects as well as insects with many more legs (also known as a metachronal wave gate). Each leg of an ant has 3 joints.

Implementing similarly functioning joints in MEMS is a daunting task. Some micro hinges suffer from particulate contamination, frictional wear, and frictional energy loss. It is not yet clear how many cycles can such joints withstand. Micro gears have similar contact friction. Some complex MEMS with gears can only operate continuously for minutes to hours before failure due to contact friction. Therefore, instead of using mechanisms with contact friction, various embodiments of the present invention use flexible piezoelectric members (for example, elongated flexible piezoelectric beams, fibers, rods and flexures) as muscles/tendons that are able to contract as well as expand.

Argument for piezo actuation. Some past attempts to use piezoelectric actuation have failed because the piezoelectric actuators had too short a stroke to be useful for microrobots. Various embodiments of the present invention include a novel way to exploit piezoelectric phenomena to achieve large (tens (10s) of microns) two degree of freedom (2 DOF) deflection for robust insect-like dexterity.

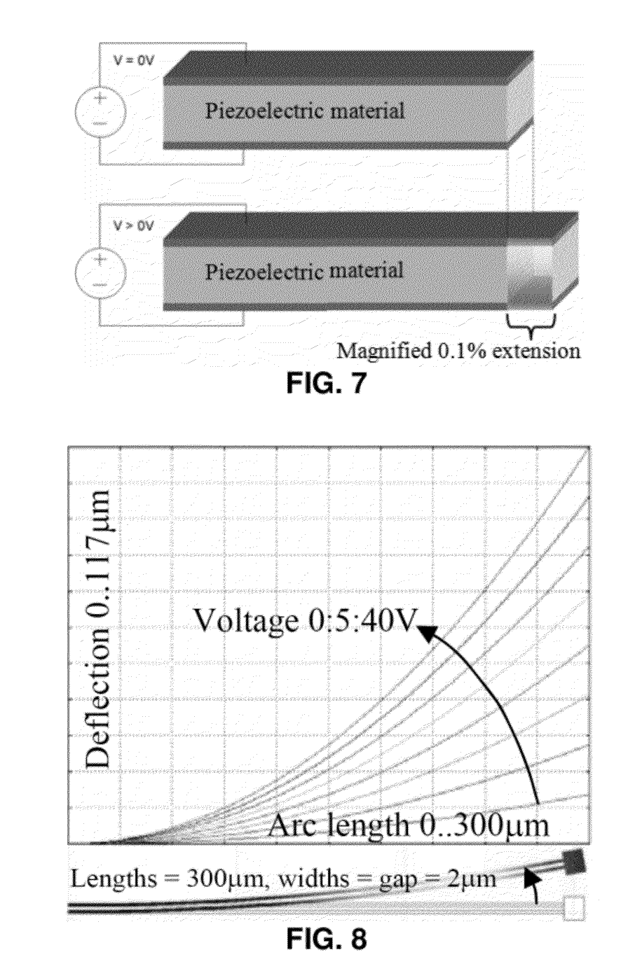

As exemplified in FIG. 7 we show a depiction of a simple piezoelectric flexure. Piezoelectric material is a dielectric that is able to deform when it is subject to an electric field. Conversely, the material is able to generate a voltage when it is subject to an applied mechanical pressure that causes deformation, which can be useful for energy harvesting. By applying a thin conductive layer to form electrodes on the top and bottom of the piezoelectric material as depicted by the darker shaded regions, the deformation of the flexure can be controlled with a controlled voltage source. Voltage causes the piezoelectric flexure to either expand or contract depending on the polarity of the applied voltage. The direction of deformation depends on the type of piezoelectric material selected or formed. In the depicted embodiment, deformation occurs in a direction that is perpendicular to the applied voltage, which is along the axial direction (lengthwise) in the embodiment depicted in FIG. 7. Additional deformation in a nonaxial direction is acceptable, but will not generally result in the lengthening or shortening of the piezoelectric members. The piezoelectric deformation due to tens (10s) of volts is typically on the order of one thousandth ( 1/1000) of its initial length. Such a seemingly small deflection may explain prior reluctance of its use in microrobotics. Furthermore, very little current flows and very little energy is dissipated, such as in the form of heat, during operation of the appendages, which may be advantageous by allowing smaller power sources or longer operation.

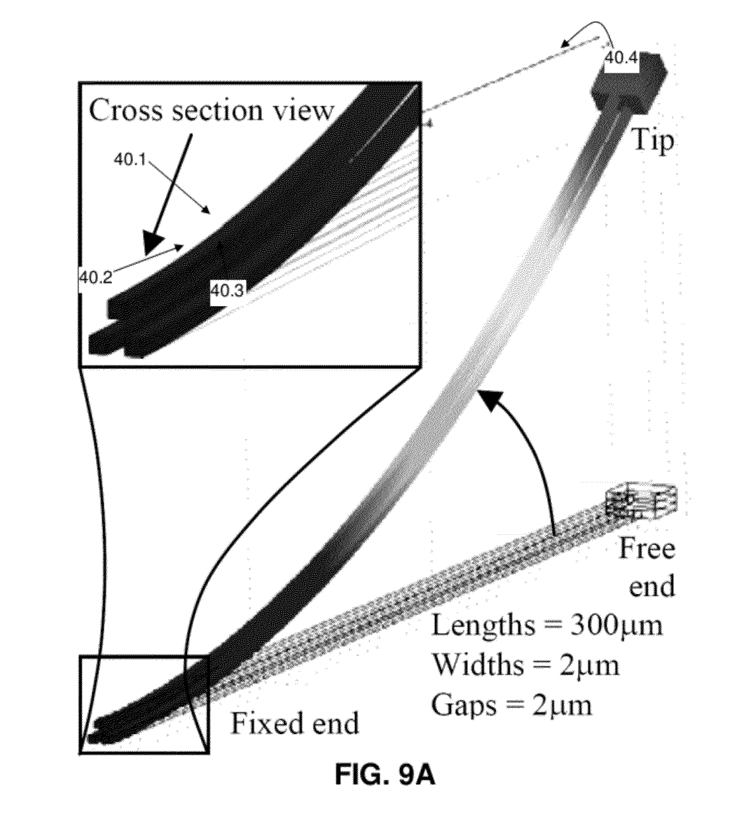

FIG. 8 shows a linear finite element analysis (FEA) simulation of a pair of piezoelectric flexures that are mechanically coupled on the far right end and mechanically fixed on the far left end according to one embodiment of the present invention. The mechanical coupling on the far right end may be of any material that connects the two flexures and preserves the proper electronic pathways of the conductors such that the appendage bends when voltage is applied. For example, the mechanical coupling may be a non-conductive material, such as the same piezoelectric material used to form the flexures. As another example, the mechanical coupling may be a conductive material that is insulated from one or more conductive electrodes (and in some embodiments can connect various electrodes) to effectuate the proper operation of the flexures.

As reflected in FIG. 8, linear modeling indicates that the flexures deflect to 39 percent (117 μm/300 μm) of the flexure's length, to arc lengths equal to the length of the flexure, and to angles of approximately 50 degrees when voltages of 40V are applied. Higher voltages can result in greater deflection. Nonlinear modeling, which accounts for the increase in stiffness as the flexures deflect, indicates that the flexures in FIG. 8 deflect to approximately 99 μm, which is approximately one-third (33 percent) of the flexures' 300 μm length.

The flexures in the appendage depicted in FIG. 8 are 300 μm long, 2 μm wide, 2 μm thick, with a 2 μm gap between the flexures. Alternate embodiments include appendages of different lengths (longer and shorter) and similar proportions to those in FIG. 8. Still further embodiments include appendages with different proportions and different dimensions depending on the intended use of the appendage. In general, longer flexures with similar proportions of thickness and width will tend to be stiffer and resist bending more than shorter flexures with similar proportions. Improved performance is generally realized with smaller appendages and flexures. In some embodiments, flexure length is at least 10 nm (nanometers) and at most 3 cm (centimeters). In other embodiments, flexure length is at least 10 μm (micrometers or microns) and at most 3 mm (millimeters). In still other embodiments, flexure length is approximately 300 μm.

Appendages with smaller gaps between the flexures tend to bend more than appendages with larger gaps between the flexures. However, certain advantages (such as increased manufacturing efficiency) may be realized by including a gap between the flexures. In some embodiments, there is no gap between flexures. In other embodiments, the gap is at least the minimum capable during manufacture (currently approximately ¼ μm) and at most approximately 200 μm. In other embodiments, the gap is approximately equal to the width and/or thickness of the flexures.

In some embodiments, the piezoelectric material is PZT, although other embodiment include different forms of piezoelectric material.

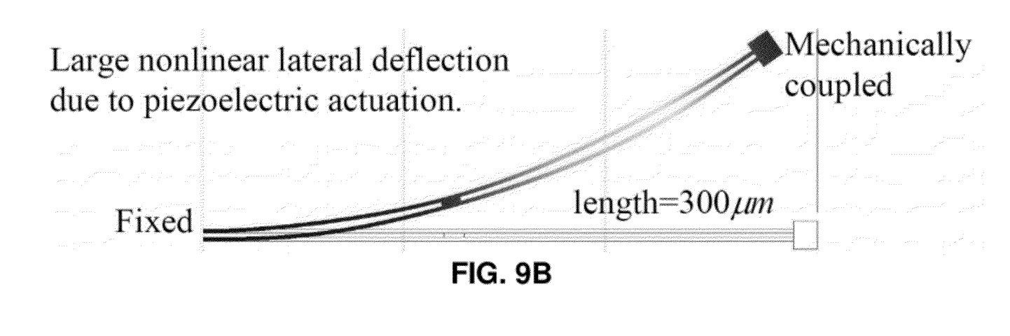

FIG. 9A shows schematically a construction of an appendage (e.g., leg 40) according to one embodiment of the present invention. This appendage is constructed by coupling a third piezoelectric flexure to the pair shown in FIG. 8. The resulting triad of piezoelectric flexures is depicted in FIG. 9A. By extending the piezoelectric actuation from planar deflection to include out-of-plane deflection, we are able to achieve 2 DOF motion. By controlling the magnitude and polarity of the applied voltage, various 2 DOF (in-plane+out-of-plane) deflections are possible. This triad of piezoelectric flexures forms a single appendage (leg or mandible), where the right end of the apparatus depicted in FIG. 9A is the foot, and the left end of the apparatus depicted in FIG. 9A is the hip, which is fixed to the body of the robot. However, the addition of a third flexure tends to make the three flexure appendage depicted in FIG. 9A stiffer than the two flexure appendage depicted in FIG. 8. For example, applying a 40V potential to the appendage in FIG. 9A results in a deflection of about 47 μm using nonlinear analysis, which is less than the 99 μm deflection of the appendage in FIG. 8 using nonlinear analysis and a 40V potential. The flexures in the appendage depicted in FIG. 9A are similar to the flexures depicted in FIG. 8 (300 μm long, 2 μm wide, 2 μm thick, with a 2 μm gap between each of the flexures).

FIG. 9B illustrates that by additionally coupling between the flexures at an intermediate position, the deflection of the appendage approximately doubles. For example, the flexure depicted in FIG. 9B can deflect to approximately 99 μm when a 40V potential is applied (nonlinear analysis), which is approximately the same deflection as the two flexure appendage depicted in FIG. 8. The intermediate mechanical couple seen on the structure constrains the flexures from bulging away from each other. Otherwise, the deflection would be about 47 μm as mentioned above. The material is PZT, the square cross section of each flexure is 2 μm, the length is 300 μm, and 40V is applied.

The intermediate coupler may be of any material that connects the two flexures, prevents their separation, and preserves the proper electronic pathways of the conductors such that the appendage bends when voltage is applied. For example, the mechanical coupling may be a non-conductive material, such as a dielectric material or the same piezoelectric material used to form the flexures. Alternate embodiments include a plurality of intermediate couplers.

Depending on the applied voltage, the appendage depicted in FIG. 9B can deflect to approximately 150 μm (one-half its length) and approximately 90 degrees. Alternate embodiments can deflect more and up to the strain limits of the material used depending on the sizing of the flexures, the gap sizes, and the applied voltage.

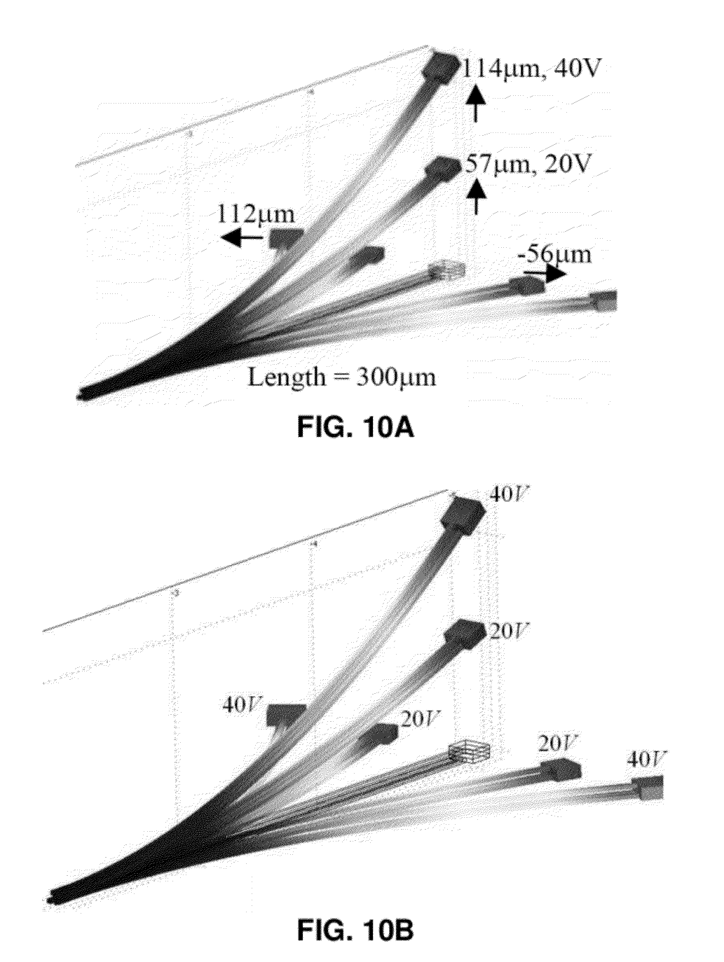

One embodiment of the present invention pertains to a mechanism that is illustrated in FIGS. 9A-10B, which shows the deflection of a triad of piezoelectric cantilevers 40.1, 40.2, and 40.3 forming a single leg. The triple-beam leg is 300 μm long. The three piezoelectric actuators 40.1, 40.2, and 40.3, connect with a common mechanical attachment 40.4 at the tip. The mechanical attachment 40.4 may be a simple coupler similar to the end coupler in FIG. 8, or may be a separately controllable device that, in addition to holding actuators 40.1, 40.2 and 40.3 together, performs various functions such as grasping, probing, piercing, digging, and carrying. With 40V applied (contracting the upper beam and extending both lower beams), the out-of-plane deflection is 114 μm. 2 DOF deflections of this leg are shown in FIGS. 10A and 10B. Since the triple-beam leg has an asymmetric cross section, some deflections may result in a small twisting of the tip and a small cross-axis deflection that may not be apparent in the figures.

In FIGS. 10A and 10B we superimpose a few voltage-induced deflections of the leg. Since the appendage has an asymmetric cross section, some deflections may result in a small twisting of the foot and a small cross-axis deflection.

While example embodiments depict the flexible piezoelectric members as being connected at the tips (e.g., the mechanical coupling of the flexures in FIG. 8 being on the far right end and the location of mechanical attachment 40.4 in FIG. 9A being at the tips of the three piezoelectric actuators 40.1, 40.2, and 40.3), alternate embodiments include flexible piezoelectric beams that extend outward from the connection location (i.e., mechanical couplings that are not at the tips of the piezoelectric members).

Still further, while coupling of the flexible piezoelectric members may occur at an intermediate position between the two ends of the piezoelectric members (e.g., the intermediate connection between the two rods in FIG. 9B being located at approximately 40 percent the length of the rods), alternate embodiments include intermediate coupling at alternate locations, such as at approximately ¼, ⅓, ½, ⅔ and ¾ the length of the rods to achieve different geometries while bent. Still further embodiments include coupling the two or more flexible piezoelectric members at a plurality of intermediate positions.

In embodiments with more than two flexible piezoelectric members, the lengths (or other dimensions such as width or thickness) of the various flexible piezoelectric members may be different. For example, flexure 40.3 may be shorter than flexures 40.1 and 40.2 in FIG. 9A. Moreover, the connection locations between various pairs of piezoelectric members may be different. For example, the one or more connection locations between flexures 40.1 and 40.2 in the embodiment depicted in FIG. 9B may be different than the connection locations between flexures 40.2 and 40.3. Varying the lengths or connection locations of the flexible piezoelectric members can produce limbs than bend in different ways and with different geometries.

It should be understood that embodiments may include additional structure to ensure the proper operation of the piezoelectric members. For example, in at least some embodiments a conductive member is included along the length of the piezoelectric member to provide a means by which a voltage may be applied across the length of the piezoelectric member. In some embodiments, the conductive member is a conductive trace that may be applied during the formation of the piezoelectric member(s). In still further embodiments, the conductive member is insulated.

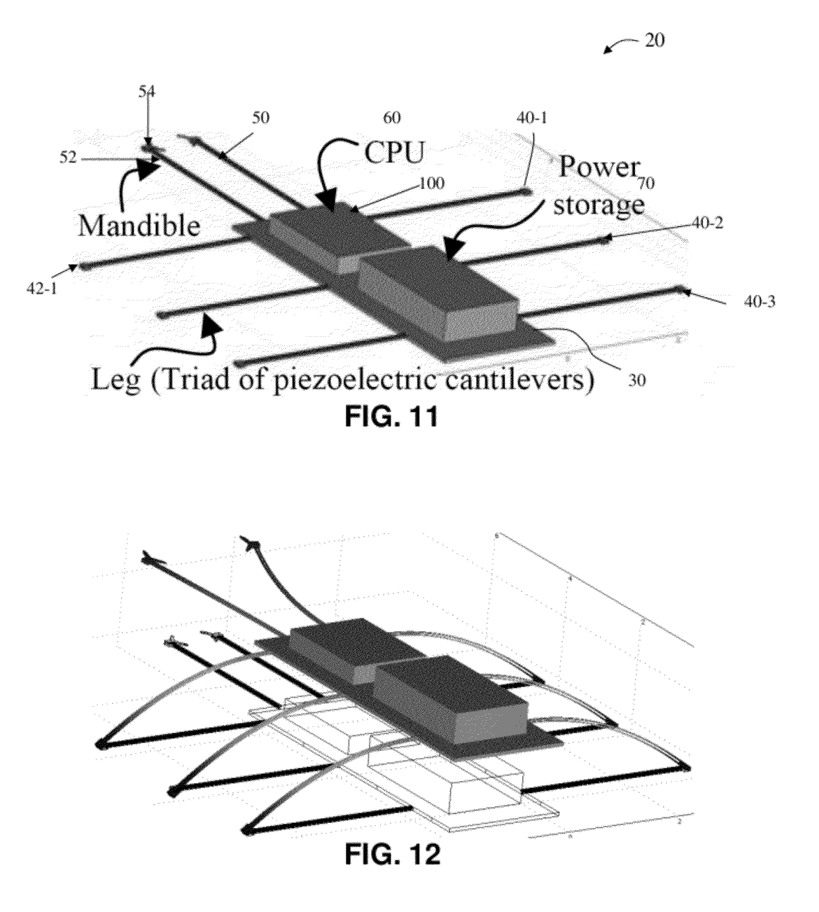

Yet another embodiment of the present invention is shown in FIGS. 11 and 12. One embodiment uses six such appendages for legs, and two for mandibles and is shown in FIG. 11 in an unactuated state.

A microid assembly 20 is shown is FIGS. 11-18 and 21. Microid 20 includes a central platform 30 to which a plurality of solid state legs 40 and 42 are attached. In one embodiment, microid 20 includes six solid state legs (40-1, 40-2, and 40-3 on one side; and 42-1, 42-2, and 42-3 on the other side). Mandibles 50 and 52 are optionally included and extend from one end of microid 20. Preferably, each mandible 50 and 52 includes an end effectuator 54 located at the distal end of the mandible. The end effectuator 54 may be a simple coupler or may be a separately controllable device that, in addition to holding appendages 42-1, 42-2, and 42-3 together, performs various functions such as grasping, probing, piercing, digging, and carrying. If all legs are actuated with 40V, microid 20 rises up with a clearance of over 100 microns between central platform 30 and ground. The legs and mandibles are able to independently move left, right, up, down.

Mandibles 50 and 52 are constructed in a manner similar to legs 40 and 42, but are shifted in their orientation to platform 30 by 90 degrees. With this orientation, actuation of the mandibles results in motion largely lateral to platform 30. In some embodiments, effectuators 54 are of a fixed geometry and capable of surrounding an object in front of microid 20 when mandibles 50 and 52 are actuated. In yet other embodiments, effectuators 54 comprise one or more pairs of piezoelectric actuators that are operable to bend in the same manner as legs 40 and 42. In those embodiments, effectuators 54 thereby have the ability to compressively grasp an object.

Microid 20 optionally includes a controller (such as a digital controller that operates in accordance with an algorithm 100, e.g., CPU 60). CPU 60 may be integrated into the robot using standard technologies. Microid 20 further includes means for storing electrical power, for example energy storage member 70, which can be of any type, including a fuel cell, solar cell, chemical battery, thin film battery, or storage capacitors. Microid 20 can also include one or more sensors for providing information about the environment to CPU 60 and one or more antennas for the exchange of information between CPU 60 and a remotely located data storage device and end user.

Using six appendages for legs, and two appendages for mandibles, we show a fully-assembled microid microrobot in FIG. 11 in its unactuated state according to one embodiment. In this embodiment, the weight of a central processing unit (CPU) 60 and the energy storage member 70 are carried on its back.

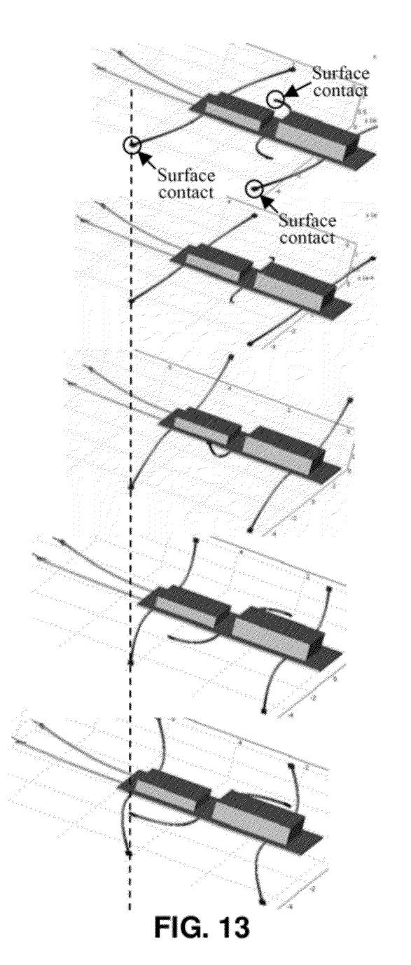

Upon actuating all appendages, the microid stands on all legs with a clearance of about 100 microns between the body and ground. See FIG. 12. The mandibles are able to spread apart, touch, bend up, or bend down depending on the applied voltages. Similarly, the legs of the microid 20 are able to independently move left, right, up, or down with varying degrees and speed. With all legs working together, the microid is able to walk in, for example, a tripod fashion, as illustrated in FIG. 13. In the figure we show a sequence of intermediate phases of a single step being taken. When walking or running in a tripod gate, two sets of three legs are simply actuated by identical voltage functions that are 180 degrees out of phase.

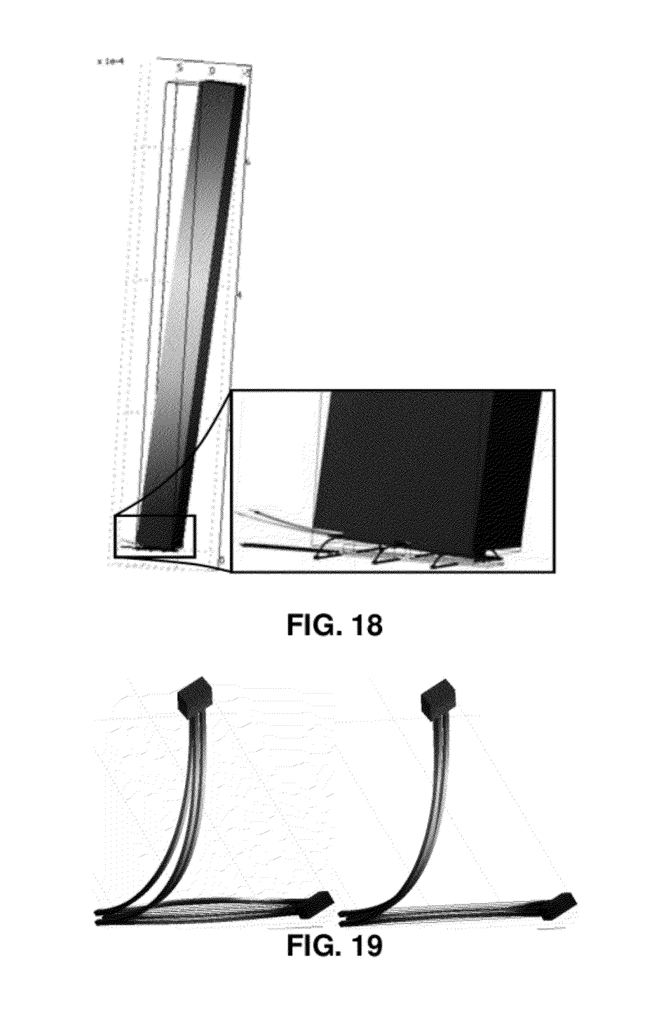

It is well known that ants are able to carry many times their own body weight. Similarly, as we show in FIG. 18, at least one embodiment of microid 20 is able to carry a heavy load, e.g., a tower of silicon, that is up to approximately 50 times the weight of microid 20. In still other embodiments, microid 20 is able to carry a heavy load that is up to approximately 350 times the weight of microid 20. In further embodiments, microid 20 is able to carry a heavy load that is up to approximately 3500 times the weight of microid 20. With such a load on its back causing its legs to nearly buckle, the microid is still able to clear the surface by a few microns. To walk with such a heavy load and still clear the surface, the microid may take one step at a time such that at least five legs are continuously supporting the load at each instant.

In order to operate outside of a controlled laboratory environment, microrobots should be able to operate in the midst of dust, sand, water, etc. In FIG. 19 we illustrate the effect of a foreign object, such as a particulate of dust or sand, lodged between the triad of piezoelectric flexures of a single leg, which will cause the flexures to separate around the particle. The performance of the leg, however, is not significantly affected. Similar results are achieved when the object is lodged between two flexures. As such, in various embodiments of the present invention, a microrobot is able to walk using legs with foreign object contamination in one or more legs.

In situations where the flexures may be pressed or held together, the performance of the leg is not significantly affected as well. Water has little effect on the piezoelectric effect. However, some embodiments include a thin layer of cladding on the electrodes of the piezoelectric flexures to help avoid a situation where the energy source could quickly drain in conductive aqueous environments without the cladding layer.

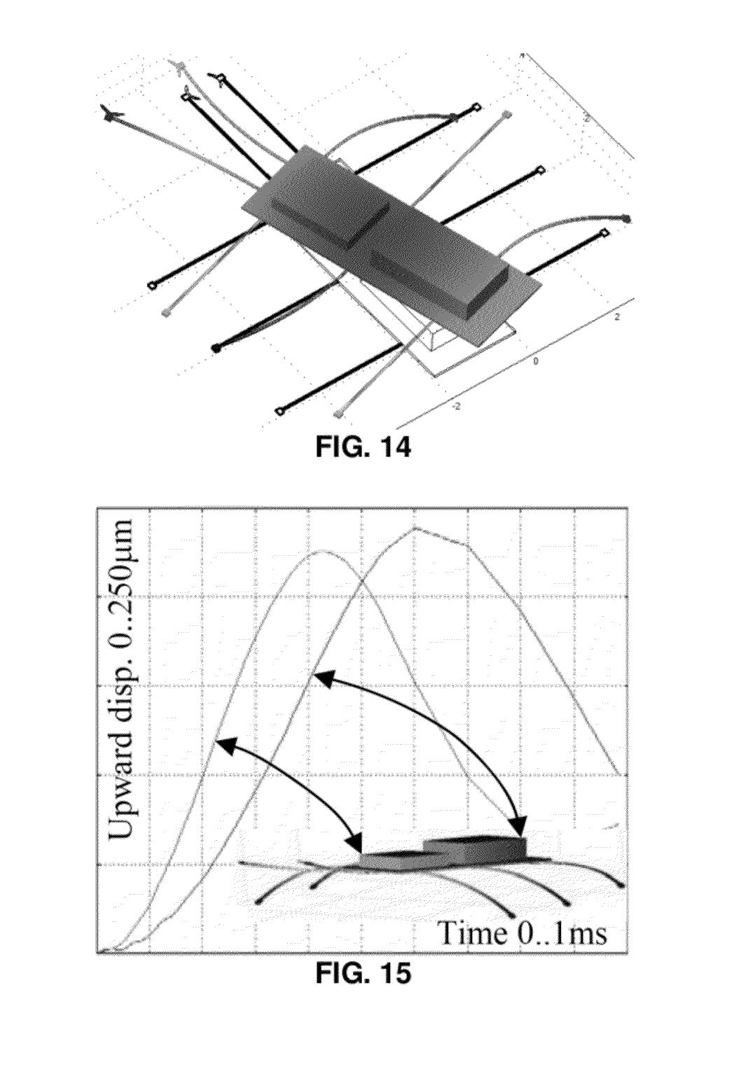

Although the microid is able to walk or run along a curved path, it is also able to rotate about a point by applying a particular combination of voltages to the legs. We illustrate the microid turning at a point in FIG. 14. With three legs positioned on the ground, the other three legs reposition themselves above ground. A complete turn is accomplished with several steps.

Jumping at the microscale can be an efficient mode of travel. For instance, jumping can be advantageous if an obstacle is too large to crawl over, or jumping onto a moving object can save travel energy and travel time. In FIG. 15 we show the results of a transient analysis of microid 20 jumping. Its initial position is the zero unactuated state. Upon applying a 40V step function, the legs quickly respond and raise the microid off of the ground a height of 2.7 cm according to one embodiment.

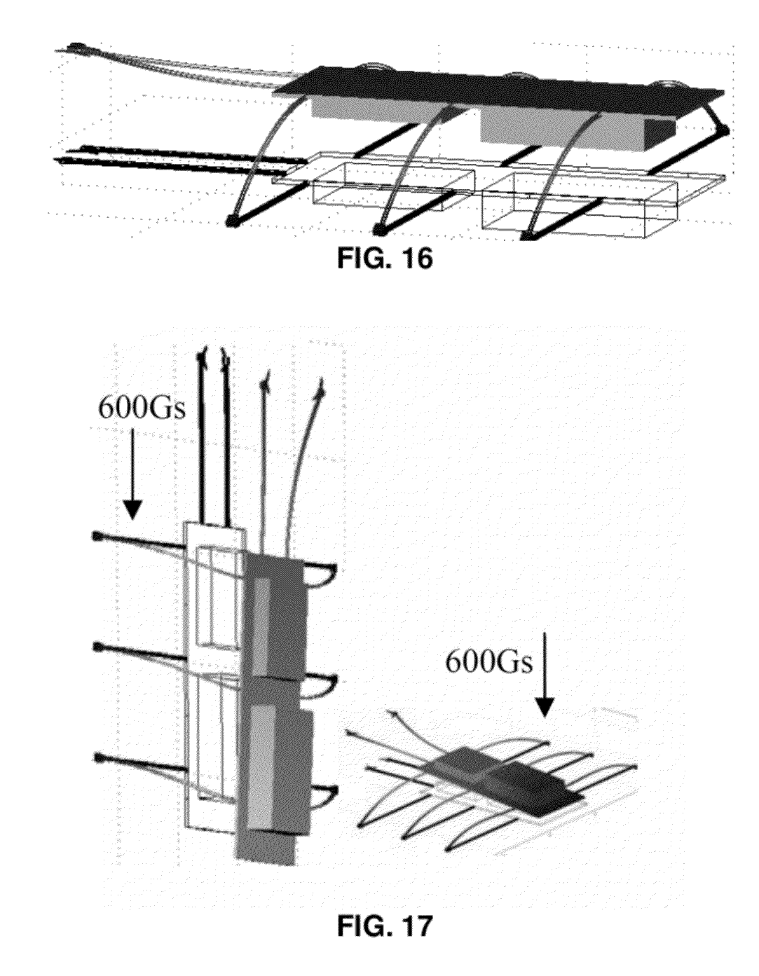

It is possible for microid 20 to end up on its back when jumping or traversing uneven terrain. Due the dexterous actuation mechanism, by reversing the polarity of the legs, the microid is able walk up-side-down, or preferably use its legs to flip over so it is right-side-up. This is an ability that insects cannot do. See FIG. 16.

Microid 20 is also able to withstand large forces. In FIG. 17 we show the microid subject to 600 G's of acceleration in both in-plane and out-of-plane directions. Embodiments of microid 20 are able to withstand strong wind speeds of up to 125 m/s (or 279 miles per hour)—about twice the speed of tornado winds. The amount of foot adhesion necessary to withstand such acceleration or wind is about 1.7 μN of force. In addition, due to the microid's solid state construction (e.g., the microid uses solid materials to generate motion instead of, for example, materials that require hinges, pins, gears or the like to generate motion), it should be able to withstand large out-of-plane externally applied forces. For instance, due to its small size, the net force a microid would experience by being stepped on by a 200 lbf person, or rolled over by 3500 lbf car, is about 0.8 mN and 15.1 mN respectively.

Although what has been shown and described is a microid having six legs arranged in generally parallel fashion on opposing sides of a platform, the present invention is not so constrained. Yet other embodiments contemplate fewer legs (such as four legs arranged in pairs on opposing sides of a platform) and more legs (such as eight legs arranged in a more radial pattern around a platform, and bearing some resemblance to a spider). Still other embodiments contemplate even larger arrays of legs, such as those arrangements that resemble a centipede, while further embodiment contemplate only three legs.

Still further, some embodiments of the present invention contemplate legs attached to platforms that provide some measure of articulation, such as a simple limited-motion hinge joint between CPU 60 and power storage device 70. Yet other embodiments of the present invention contemplate an articulating platform in which the angular relationship of one portion of the platform to another portion of the platform can be altered by one or more piezoelectric actuators embedded within the platform.

Controlling the legs such that they are working together, the microid is able to walk in, for example, a tripod fashion, as illustrated in FIG. 13. Furthermore, since the legs are solid state and responds rapidly to control inputs, embodiments of the microid are able to walk rapidly, especially when compared to other robots.

FIGS. 14-19 depict capabilities present in at least some embodiments of the present invention. This microid is also able to walk over small obstacles; able to turn (FIG. 14); able to jump in various directions (FIG. 15); able to walk upside down (or jump upside down) if flipped on its back (FIG. 16); able to walk while withstanding hundreds of Gs (FIG. 17); able to walk while carrying loads as much as a few thousand times its weight (FIG. 18); and able to function while contaminated with, for example, small particulates (FIG. 19).

Various embodiments described herein have a combination of material properties, geometries, and configurations that optimize performance and help improve fabrication robustness. Some of these aspects include mask alignment mismatch and other nonidealities. Microids according to some embodiments are extremely robust to mask misalignments. For example, microids manufactured with mask alignments up to (and potentially greater than) 1 μm, which is significantly larger than current manufacturing tolerances, will still walk and function, although potentially with a “limp” or some other similar irregularity.

Electro micrometrology (EMM) can be used to extract geometric and material properties from the fabricated device, and the parameters can be imported into the computer model in order to match measurement with simulation. One purpose of matching simulation with measurement is to more completely understand and characterize the microid for its strategic use. The simulation can also permit examination of the affect of modifying the overall size and varying configurations of the microid. There can be significant benefits and trade-offs that go with parameterization. Although only limited types of microids are shown herein, there is a very large design space. Various modes of energy harvesting and power dissipation through the microid's piezoelectric appendages are also possible in various embodiments.

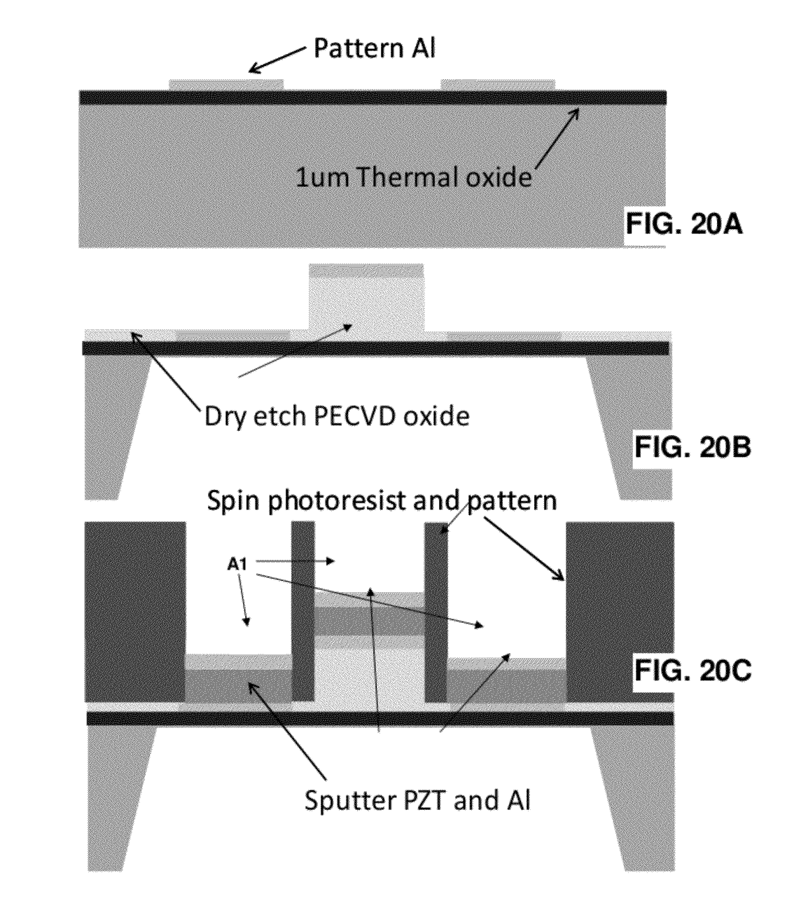

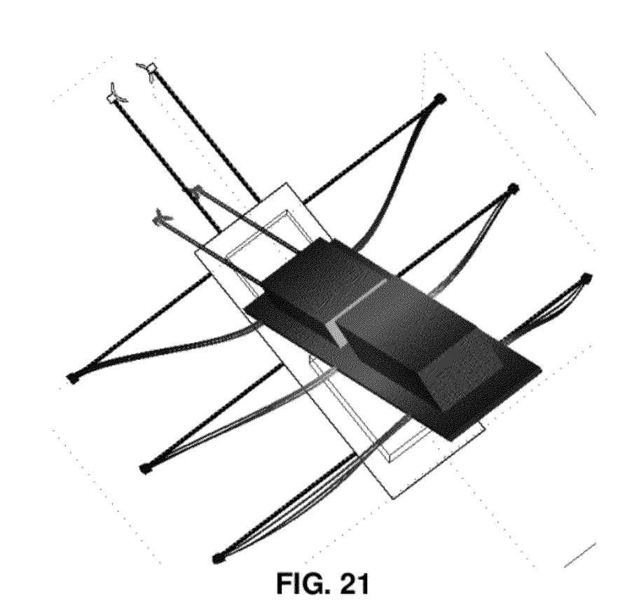

Fabrication and measurement. One particular fabrication process useful in some embodiments of the present invention is depicted in FIGS. 20A, 20B, and 20C. However, the invention is not so constrained, and other embodiments of the present invention contemplate other processes, some of which may be able to provide nearly 100% yield. Such high yield is possible due to design robustness, and due to the simplicity of the actuation principle, which is much less complicated than comb drives, hinges, and other mechanisms used in many conventional microrobots.

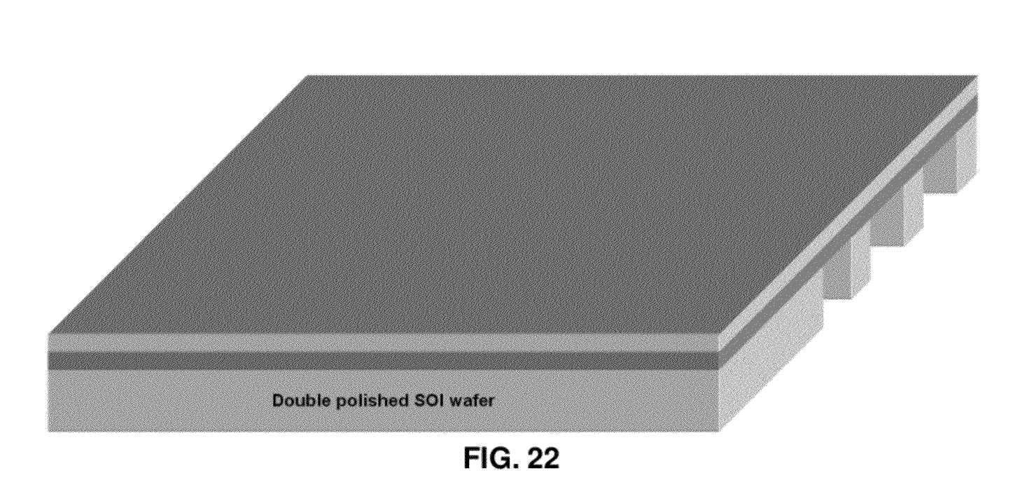

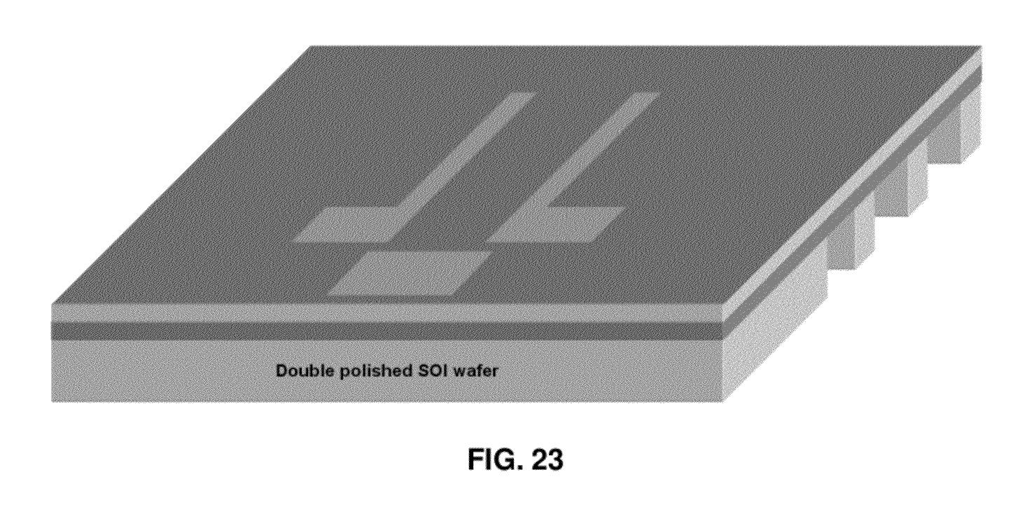

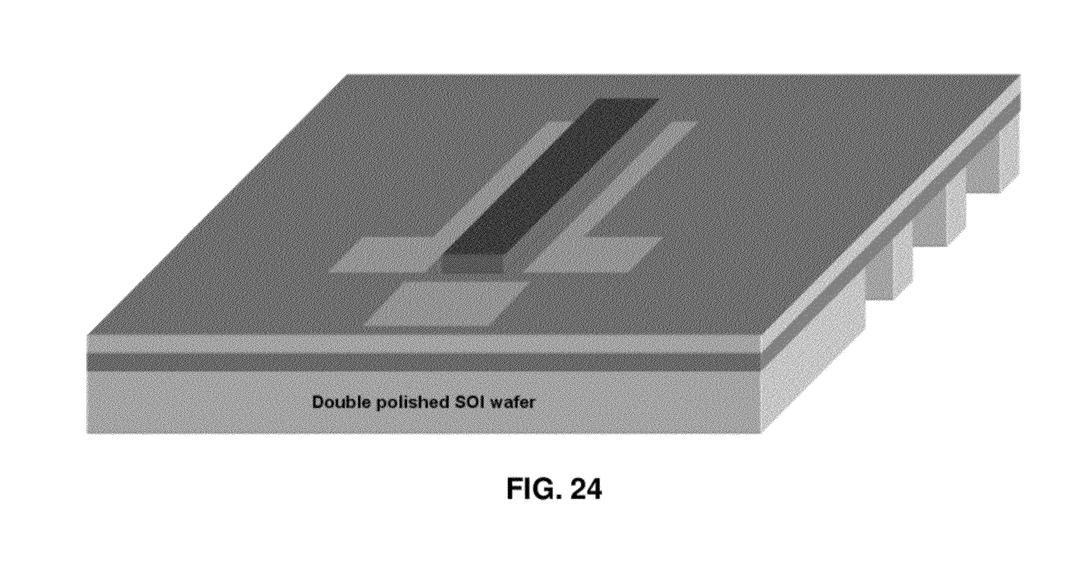

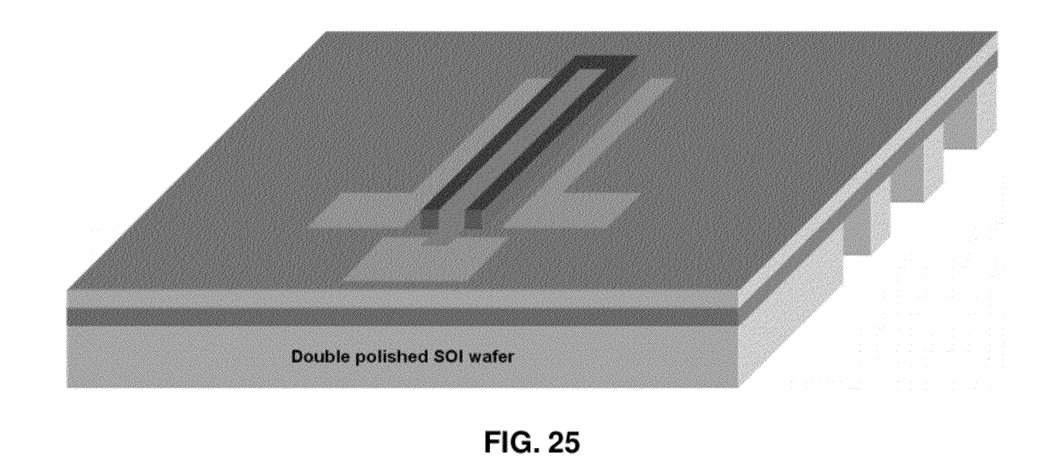

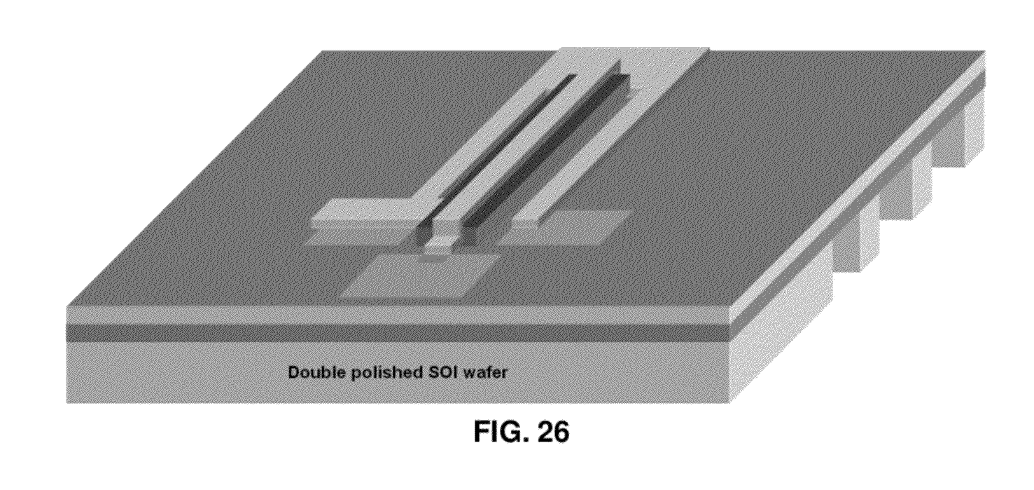

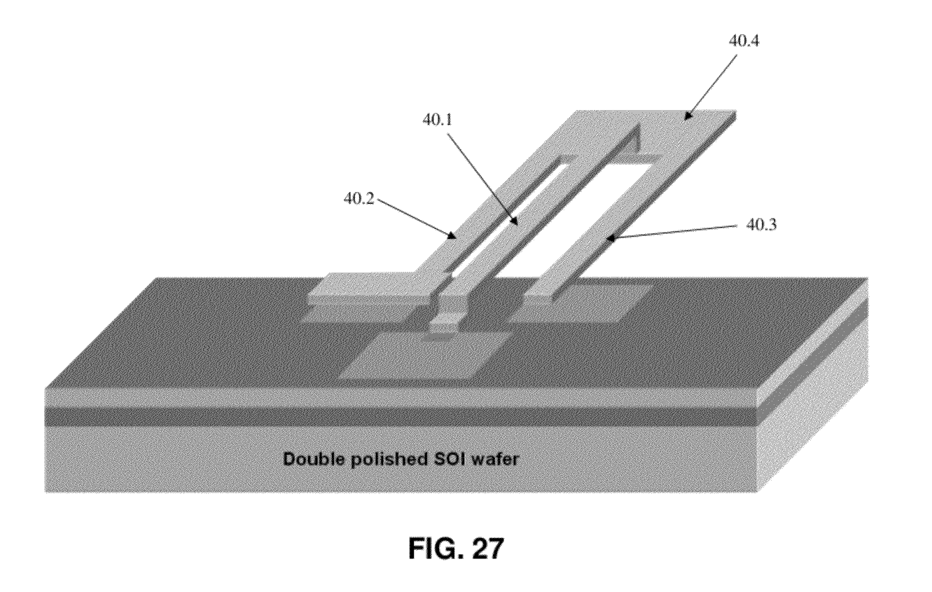

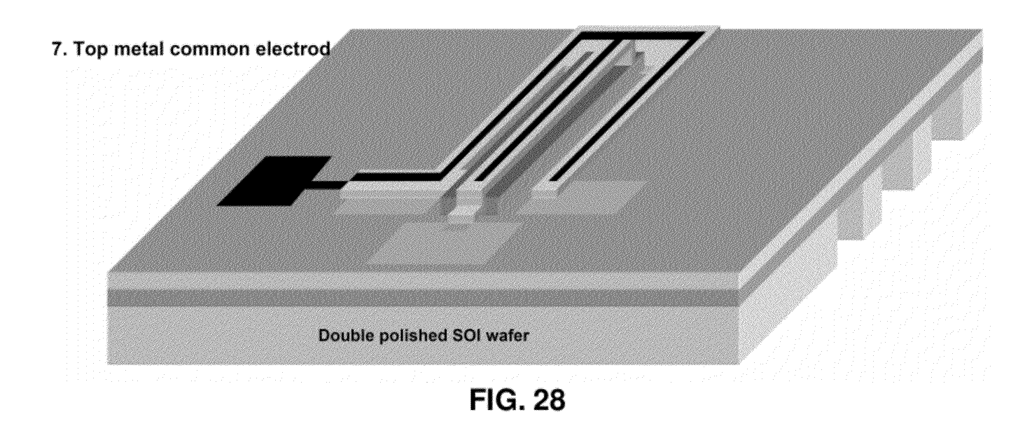

Other processing steps are shown in FIGS. 22-28. FIG. 22 depicts a silicon wafer having a cross-hatched pattern on its backside. FIG. 23 shows the wafer of FIG. 22 with the deposition of three aluminum patterns for the three actuation voltages that can be applied to a leg assembly 40. FIG. 24 shows the application of a sacrificial layer to the silicon wafer for the deposition of an elevated central leg piezoelectric actuator 40.1. FIG. 25 shows a patterning of bottom metal for central piezoelectric actuator 40.1. FIG. 26 shows a deposited pattern of piezoelectric material for each of the three piezoelectric actuators 40.1, 40.2, and 40.3, and also the application of a top metal layer for a ground voltage. FIG. 28 shows the ground plane electrode. FIG. 27 shows the apparatus of FIG. 26 with a portion of the silicon wafer having been dissolved, and subsequent to the release of the partially assembled leg structure 40.

Applications are expected to include surveillance (i.e. smart-dust with legs), aid in search and rescue, and micro assembly, organic crop protection, etc.

Energy harvesting is possible through piezoelectric transduction of vibrational modes. An exaggerated mode is shown, FIG. 21. Variations in resonant frequency are achieved by a microid carrying various loads. FIG. 21 depicts a snap-shot of Mode 1=853 Hz (shown) where the surface and/or the microid has been perturbed and the micron's appendages are no longer in their nominal position, such as may be depicted in FIG. 12. The energy imparted to the appendages from the environment to cause this type of perturbation may be scavenged and stored. Other embodiments include Mode 3=1.2 kHz and mode 5=11 kHz, which are not shown.

Although the material PZT has been disclosed as one possible piezoelectric material for forming embodiments of the present invention, other embodiments utilize other materials with similar properties as would be understood by one of ordinary skill in the art. Moreover, alternate embodiments include flexible piezoelectric members of different compositions, e.g., one flexible piezoelectric member may be constructed of one piezoelectric material while the other flexible piezoelectric member(s) is constructed of a different piezoelectric material.

It should be appreciated by one of ordinary skill in the art that the representative voltages disclosed herein, e.g., 40V, are by example only and nonlimiting. Voltages in excess of 40V may be used provided that proper operation of the appendages in maintained. With a 2 μm gap between piezoelectric beams, conduction across the gap (arcing) can begin to occur when voltages approach 200V. Larger gaps will tend to permit higher voltages without arcing, but will also generally tend to decrease the maximum bending possible by the appendage.

Although the above description specifically refers to mobile robots, alternate embodiments may include movable appendages attached to alternate devices. For example, in some embodiments the movable appendages are probes, such as probes used with various types of scanning probe microscopy, e.g., atomic force microscopes and scanning tunneling microscopes.

Although references may be made to different simulations or models of the present invention, it should be understood that these simulations and models are merely one way of approximating how various embodiments of the present invention operate and are not intended to limit the operation of these embodiment, there being a difference between embodiments of the present invention and models of these embodiments.

While illustrated examples, representative embodiments and specific forms of the invention have been illustrated and described in detail in the drawings and foregoing description, the same is to be considered as illustrative and not restrictive or limiting. The description of particular features in one embodiment does not imply that those particular features are necessarily limited to that one embodiment. Features of one embodiment may be used in combination with features of other embodiments as would be understood by one of ordinary skill in the art, whether or not explicitly described as such. Exemplary embodiments have been shown and described, and all changes and modifications that come within the spirit of the invention are desired to be protected.

What is claimed is:

1. An apparatus, comprising:
a first flexible piezoelectric member; and
a second flexible piezoelectric member, the second flexible piezoelectric member being attached to the first flexible piezoelectric member in at least two locations, wherein at least one of the first and second flexible piezoelectric members bends in response to the application of electricity to at least one of the first and second flexible piezoelectric members.

2. The apparatus of claim 1, wherein the length of the at least one piezoelectric members to which electricity is applied changes.

3. The apparatus of claim 1, wherein at least one flexible piezoelectric member deflects a distance equal to at least one-third (⅓) the length of the piezoelectric member in response to the application of electricity to at least one of the first and second flexible piezoelectric members.

4. The apparatus of claim 1, wherein the first and second flexible piezoelectric members bend in response to the application of electricity to at least one of the first and second flexible piezoelectric members.

5. The apparatus of claim 1, wherein the first and second flexible piezoelectric members are separated from one another by a gap in at least on location.

6. The apparatus of claim 1, wherein the length of each flexible piezoelectric member is at most 3 mm.

7. The apparatus of claim 1, further comprising:
a third flexible piezoelectric member, the third flexible piezoelectric member being attached to the first and second piezoelectric members in at least two locations, and wherein at least one of the first, second and third flexible piezoelectric members bends in response to the application of electricity to at least one of the first, second and third flexible piezoelectric members.

8. The apparatus of claim 7, wherein the first, second and third flexible piezoelectric members form an appendage of a robot, and wherein the robot includes a plurality of appendages.

9. The apparatus of claim 8, wherein the robot moves by bending the plurality of appendages.

10. The apparatus of claim 8, wherein the robot jumps by bending the plurality of appendages.

11. The apparatus of claim 8, further comprising:
an energy storage member, wherein electricity generated by movement of at least one of the plurality of appendages due to external forces is stored in the energy storage member.

12. The apparatus of claim 8, wherein the robot moves by bending the plurality of appendages while carrying a load weighing 350 times the weight of the robot.

13. The apparatus of claim 8, wherein the robot bends the plurality of appendages in directions that permit the robot to walk in an upside-down orientation.

14. The apparatus of claim 8, wherein the robot walks using at least one appendage with an object lodged between at least two of the piezoelectric members in the at least one appendage.

15. The apparatus of claim 7, wherein the first, second and third flexible piezoelectric members form a portion of an atomic force microscope.

16. The apparatus of claim 1, further comprising:
a third flexible piezoelectric member, the first, second and third flexible piezoelectric members being attached to one another in at least three locations, and wherein at least one of the first, second and third flexible piezoelectric members bends in response to the application of electricity to at least one of the first, second and third flexible piezoelectric members.

17. An apparatus, comprising:
a robot body with an upper portion and a lower portion; and
a plurality of appendages connected to the robot body;
wherein the robot body and the plurality of appendages move across a surface by moving the plurality of appendages while the upper portion is oriented above the lower portion; and
wherein the robot body and the plurality of appendages move across a surface by moving the plurality of appendages while the lower portion is oriented above the upper portion.

18. The apparatus of claim 17, wherein each of the plurality of appendages comprises a plurality of flexible piezoelectric members connected to one another.

19. The apparatus of claim 18, wherein each of the plurality of appendages includes at least one location where the plurality of flexible piezoelectric members are separated by a gap from one another.

20. The apparatus of claim 17, wherein the robot body and the plurality of appendages jump using the plurality of appendages while the upper portion is oriented above the lower portion, and
wherein the robot body and the plurality of appendages jump using the plurality of appendages while the lower portion is oriented above the upper portion.

21. The apparatus of claim 17, further comprising:
an energy storage member, wherein energy generated by movement of at least one of the plurality of appendages due to external forces is stored in the energy storage member.

22. The apparatus of claim 17, wherein the robot body and the plurality of appendages move across a surface with foreign object contamination in at least one of the plurality of appendages.

23. The apparatus of claim 17, wherein the robot body and the plurality of appendages move while carrying a load weighing 350 times the weight of the robot body and the plurality of appendages.

24. A method of forming a microrobot, comprising the acts of:
forming a plurality of appendages, each appendage formed by
forming at least two flexible piezoelectric members, each piezoelectric member including a first and second portion, and
connecting the first portions of the at least two flexible piezoelectric members to one another;
connecting the second portions of each flexible piezoelectric member to one another; and
connecting an electrical source to at least one flexible piezoelectric member of each appendage, the electrical source supplying electrical energy to each of the flexible piezoelectric members to which the electrical source is connected.

25. The method of claim 24, wherein each flexible piezoelectric member includes a third portion, and wherein the act of forming a plurality of appendages includes
connecting the third portions of the at least two flexible piezoelectric members of each appendage to one another, and
forming at least two gaps between the two flexible piezoelectric members.

26. The method of claim 24, wherein each flexible piezoelectric member includes a third portion, and wherein the act of forming a plurality of appendages includes forming a gap between the third portions of the at least two flexible piezoelectric members of each appendage.

27. The method of claim 24, wherein the act of forming a plurality of appendages includes
forming at least three flexible piezoelectric members, each piezoelectric member including a first and second portion, and
connecting the first portions of the at least three flexible piezoelectric members to one another.

28. The method of claim 26, wherein each flexible piezoelectric member includes a third portion, and wherein the act of forming a plurality of appendages includes connecting the third portions of the at least three flexible piezoelectric members of each appendage to one another.

29. The method of claim 24, further comprising:
connecting the first portions of the plurality of flexible piezoelectric members and the electrical source to a controller that individually controls the electricity applied to each of the flexible piezoelectric members to which the controller is connected.
